(19) United States
(12) Patent Application Publication
(10) Pub. No.: US 2004/0065255 A1
(43) Pub. Date: Apr. 8, 2004

(54) Cyclical layer deposition system

(75) Inventors: Michael X. Yang, Palo Alto, CA (US); Joseph Yudovsky, Campbell, CA (US); Hyungsuk Yoon, San Jose, CA (US); Xiaoxiong Yuan, Cupertino, CA (US)

Correspondence Address: PATENT COUNSEL, APPLIED MATERIALS, INC., Legal Affairs Department, P.O. BOX 450A, Santa Clara, CA, 95052, US

(73) Assignee: Applied Materials, Inc.

(21) Appl. No.: 10/356,251

(22) Filed: Jan. 31, 2003

Related U.S. Application Data
(60) Provisional application No. 60/415,608, filed on Oct. 2, 2002.

(51) Int. Cl. C23C 16/00

(52) U.S. Cl. 118/715

(57) ABSTRACT

Embodiments of the invention are generally directed to a cyclical layer deposition system, which includes a processing chamber; at least one load lock chamber connected to the processing chamber; a plurality of gas injectors connected to the processing chamber. The gas injectors are configured to deliver gas streams into the processing chamber. The system further includes at least one shuttle movable between the at least one load lock chamber and the processing chamber.

### CROSS-REFERENCE TO RELATED APPLICATIONS

This application claims benefit of U.S. provisional patent application serial No. 60/415,608, filed on Oct. 2, 2002, which is herein incorporated by reference.

### BACKGROUND OF THE INVENTION

1. Field of the Invention

Embodiments of the present invention generally relate to methods and apparatus for depositing materials on a substrate surface using cyclical layer deposition.

2. Description of the Related Art

As feature sizes for semiconductor substrates have become smaller and demand for efficient delivery of two or more precursors on a substrate surface have increased along with the need for more throughput, the desire to economically fabricate advanced semiconductor devices pushes processing sequences to ever-increasing levels of performance and productivity. Slow rates of deposition due to multiple processing steps, such as those of a conventional ALD process, are not conducive to achieving competitive performance and productivity. Further, ALD processes involving TiN, SiN and Si deposition require a low deposition rate with high film thickness. Many current systems, however, do not adequately meet such processing requirements.

Significant efforts have recently been made to find ways to meet current processing demands and requirements. One of the processes capable of meeting such demands and requirements is a cyclical layer deposition (CLD) process. Generally, CLD exposes a substrate to alternating reactants, and utilizes a phenomena known as adsorption, including physisorption and/or chemisorption, to deposit alternating layers of reactive molecules on a substrate surface.

Therefore, a need exists for an improved method and apparatus for depositing materials on a substrate surface using CLD.

### SUMMARY OF THE INVENTION

Embodiments of the invention are generally directed to a cyclical layer deposition system, which includes a processing chamber; at least one load lock chamber connected to the processing chamber; and a plurality of gas injectors connected to the processing chamber and configured to deliver gas streams into the processing chamber. The system further includes at least one shuttle movable between the at least one load lock chamber and the processing chamber.

In one embodiment, the invention is directed to a method of processing a substrate, comprising: disposing a substrate in a first load lock chamber; transferring the substrate from the load lock chamber to a processing chamber; moving the substrate through the processing chamber; and delivering one or more gas streams into the processing chamber and across a surface of the substrate while moving the substrate through the processing chamber.

In another embodiment, the invention is directed to a method of processing a substrate, comprising: disposing a substrate in a first load lock chamber; transferring the substrate from the load lock chamber to a processing chamber; moving the substrate through the processing chamber; and delivering two or more gas streams into a plurality of reaction zones defined within the processing chamber.

In yet another embodiment, the invention is directed to a method of processing a plurality of substrates, comprising: moving a plurality of substrates through a processing chamber; and delivering one or more gas streams into the processing chamber and across a surface of each substrate while moving the substrates through the processing chamber.

In still another embodiment, the invention is directed to a method of processing a plurality of substrates, comprising: moving the substrates through the processing chamber in a circular fashion; and delivering one or more gas streams into the processing chamber and across a surface of each substrate while moving the substrates through the processing chamber.

### BRIEF DESCRIPTION OF THE DRAWINGS

So that the manner in which the above recited features of the present invention can be understood in detail, a more particular description of the invention, briefly summarized above, may be had by reference to the embodiments illustrated in the appended drawings and described in the specification. It is to be noted, however, that the appended drawings illustrate only typical embodiments of this invention and are therefore not to be considered limiting of its scope, for the invention may admit to other equally effective embodiments.

FIG. 1 is a schematic top view of a cyclical layer deposition system or reactor in accordance with an embodiment of the invention;

FIG. 2 is a schematic side view of a cyclical layer deposition system or reactor in accordance with an embodiment of the invention;

FIG. 3 is a schematic top view of a cyclical layer deposition system or reactor in which a plurality of substrates may be processed in accordance with an embodiment of the invention;

FIG. 4 is a schematic side view of a cyclical layer deposition system or reactor in which a plurality of substrates may be processed in accordance with an embodiment of the invention; and

FIG. 5 is a schematic top view of a cyclical layer deposition system or reactor in accordance with an embodiment of the invention.

### DETAILED DESCRIPTION OF THE PREFERRED EMBODIMENT

The invention is directed to various embodiments of a cyclical layer deposition reactor or system. In one embodiment, the system includes a processing chamber connected to at least one load lock chamber. The load lock chamber may be disposed at one end of the processing chamber or at both ends. The load lock chamber generally provides a mechanism for substrates to be delivered into the processing chamber and retrieved from the processing chamber. The processing chamber includes at least one shuttle for carrying a substrate. The processing chamber further defines a plurality of gas ports, vacuum ports and partitions. The gas ports are connected to either a precursor gas injector or a purge gas injector, which are configured to deliver gas streams into the processing chamber. The vacuum ports are connected to a pumping system configured to evacuate the gas streams out of the processing chamber. The gas ports and the vacuum ports are positioned in the chamber so as to provide a laminar flow of the gas streams across the substrate surface. In one embodiment, the gas ports are positioned across from the vacuum ports. Furthermore, each gas port is separated by a partition. Each partition extends downward from the top portion of the processing chamber to a distance proximate the substrate surface so as to limit cross-contamination between the gas streams.

In another embodiment, the processing chamber has an annular shape. In such an embodiment, the gas ports are disposed on an inner perimeter portion of the processing chamber, while the vacuum ports are disposed on an outer perimeter portion of the chamber, and the partitions are disposed between the inner perimeter portion and the outer perimeter portion. In this manner, the substrates are processed as they are carried around the perimeter of the processing chamber.

The words and phrases used herein should be given their ordinary and customary meaning in the art by one skilled in the art unless otherwise further defined. The term “compound” is intended to include one or more precursors, reductants, reactants, and catalysts, or a combination thereof. The term “compound” is also intended to include a grouping of compounds, such as when two or more compounds are injected in a processing system at the same time. For example, a grouping of compounds may include one or more catalysts and one or more precursors. A wide variety of semiconductor processing precursor, compounds and reactants may be used. Examples may include titanium tetrachloride (TiCl4), tungsten hexafluoride (WF6), tantalum pentachloride (TaCl5), titanium iodide (Til4), titanium bromide (TiBr4), tetrakis(dimethylamido) titanium (TDMAT), pentakis(dimethyl amido) tantalum (PDMAT), tetrakis(diethylamido) titanium (TDEAT), tungsten hexacarbonyl (W(CO)6), tungsten hexachloride (WCl6), tetrakis(diethylamido) titanium (TDEAT), pentakis (ethyl methyl amido) tantalum (PEMAT), pentakis(diethylamido)tantalum (PDEAT), ammonia (NH3), hydrazine (N2H4), monomethyl hydrazine (CH3N2H3), dimethyl hydrazine (C2H6N2H2), t-butylhydrazine (C4H9N2H3), phenylhydrazine (C6H5N2H3), 2,2′-azoisobutane ((CH3)6C2N2), ethylazide (C2H5N3), and nitrogen (N2), for example.

The term “reaction zone” is intended to include any volume within a processing chamber that is in fluid communication with a substrate surface being processed. A reaction zone, therefore, includes a volume adjacent a gas port, a volume above the substrate surface, and a volume adjacent a vacuum port. More particularly, the reaction zone includes a volume downstream of each gas port and above the substrate surface.

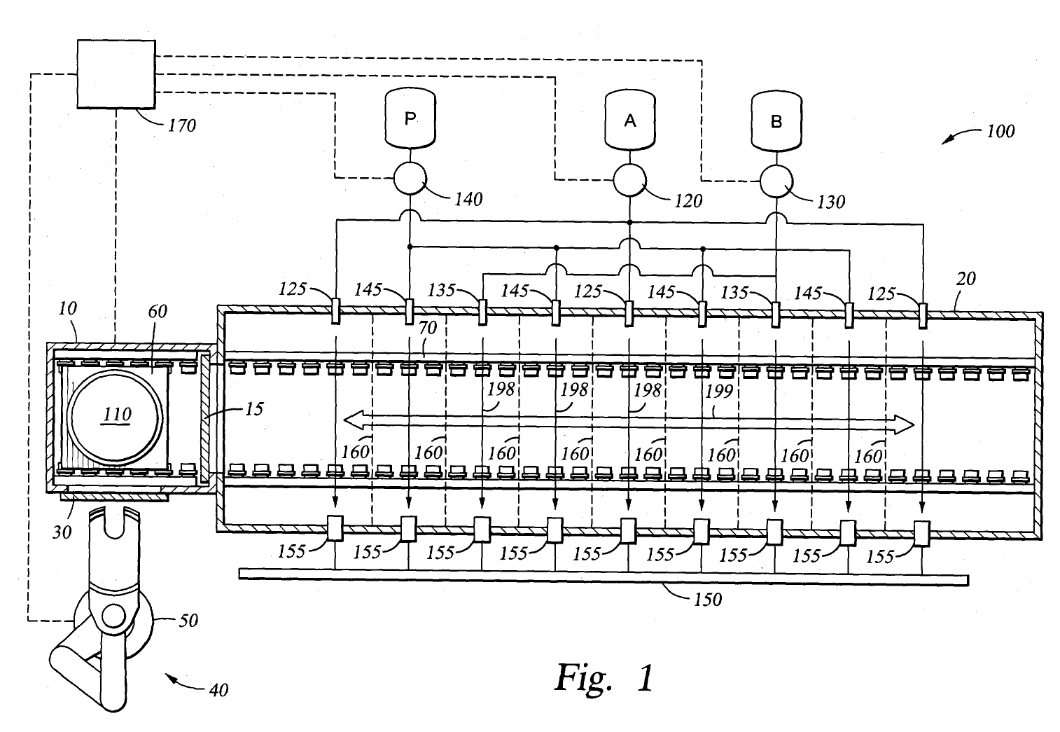

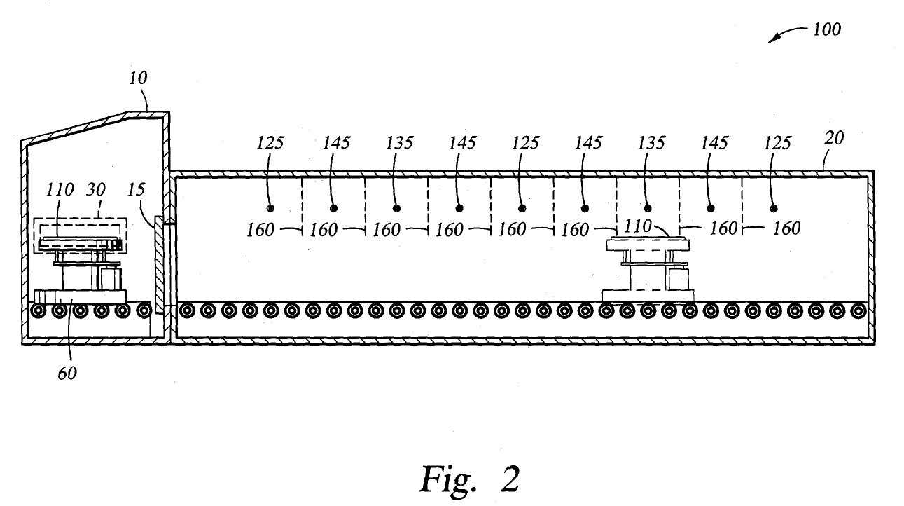

FIGS. 1 and 2 illustrate a cyclical layer deposition system or reactor 100 in accordance with an embodiment of the invention. The system 100 includes a load lock chamber 10 and a processing chamber 20. The processing chamber 20 is generally a sealable enclosure, which is operated under vacuum, or at least low pressure. The processing chamber 20 is isolated from the load lock chamber 10 by an isolation valve 15. The isolation valve 15 seals the processing chamber 20 from the load lock chamber 10 in a closed position and allows a substrate 110 to be transferred from the load lock chamber 10 through the valve to the processing chamber 20 and vice versa in an open position.

The load lock chamber 10 includes a valve 30 that opens to a receiving station 40 that is serviced by a robot 50. The robot 50 is configured to deliver and retrieve substrate 110 to and from the load lock chamber 10 through the valve 30. Although the valve 30 is illustrated in FIG. 1 as being disposed on a side of the load lock chamber 10 proximate a lateral side of the processing chamber 20, the valve 30 may be disposed on other available sides of the load lock chamber 10. In this manner, the robot 50 may deliver substrate 110 through the valve 30 disposed on a side other than that shown in FIG. 1. In addition to the service station 40 and the robot 50, any conventional substrate transfer assembly may be used, such as a robotic substrate transfer assembly described in the commonly assigned U.S. Pat. No. 4,951,601, entitled “Multi-chamber Integrated Process System”, which is incorporated by reference herein. The robot 50 may be generally known as an atmospheric robot and may be commercially available from such manufacturers as MECS, RORTZ, JEL, Daihen, Komatsu and other manufacturers known to those in the art.

The system 100 further includes a shuttle 60 for carrying the substrate 110. The shuttle 60 is movable in both directions (as indicated by arrow 199) between the load lock chamber 10 and the processing chamber 20. The shuttle 60 may be controlled by a system computer, such as a mainframe, or by a chamber-specific controller, such as a programmable logic controller. A sensor (not shown) may be provided to determine the position of the shuttle 60 and to provide input to the computer or the controller to control the shuttle movement. The system 100 further includes a track 70 and a reversible motor or gear assembly (not shown) for moving the shuttle 60. The track 70 may include a plurality of guide rollers and pinion gears. The quantity of guide rollers and pinion gears may vary depending on the length of the chambers, the length of the shuttle 60 and the size of the substrate.

Alternatively, in lieu of shuttle 60, the system 100 may include a loading shuttle (not shown) and a process shuttle (not shown). The loading shuttle is configured to transfer substrate 110 from the load lock chamber 10 to the process shuttle prior to processing substrate 110. The process shuttle is configured to carry substrate 110 through the processing chamber 20. In this alternative, two tracks are generally disposed in the system 100, in which each track provides a path for moving the shuttle. The embodiments described herein are merely examples for moving or carrying substrate 110 in the system 100. The invention contemplates other mechanisms for carrying substrate 110, such as one described in the commonly assigned U.S. Pat. No. 6,298,685, entitled “Consecutive Deposition System”, which is incorporated by reference herein.

The shuttle 60 may be a heated shuttle so that the substrate may be heated for processing. As an example, the shuttle 60 may be heated by heat lamps, a heating plate, resistive coils, or other heating devices, disposed underneath the shuttle 60.

The system 100 further includes a precursor injector 120, a precursor injector 130 and a purge gas injector 140. The injectors 120, 130, 140 may be controlled by a system computer, such as a mainframe, or by a chamber-specific controller, such as a programmable logic controller. The precursor injector 120 is configured to inject a continuous (or pulse) stream of a reactive precursor of compound A into the processing chamber 20 through a plurality of gas ports 125. The precursor injector 130 is configured to inject a continuous (or pulse) stream of a reactive precursor of compound B into the processing chamber 20 through a plurality of gas ports 135. The purge gas injector 140 is configured to inject a continuous (or pulse) stream of a non-reactive or purge gas into the processing chamber 20 through a plurality of gas ports 145. The purge gas is configured to remove reactive material and reactive by-products from the processing chamber 20. The purge gas is typically an inert gas, such as, hydrogen, nitrogen, argon and helium. Gas ports 145 are disposed in between gas ports 125 and gas ports 135 so as to separate the precursor of compound A from the precursor of compound B, thereby avoiding cross-contamination between the precursors.

In another aspect, a remote plasma source (not shown) may be connected to the precursor injector 120 and the precursor injector 130 prior to injecting the precursors into the chamber 20. The plasma of reactive species may be generated by applying an electric field to a compound within the remote plasma source. Any power source that is capable of activating the intended compounds may be used. For example, power sources using DC, radio frequency (RF), and microwave (MW) based discharge techniques may be used. If an RF power source is used, it can be either capacitively or inductively coupled. The activation may also be generated by a thermally based technique, a gas breakdown technique, a high intensity light source (e.g., UV energy), or exposure to an x-ray source. Exemplary remote plasma sources are available from vendors such as MKS Instruments, Inc. and Advanced Energy Industries, Inc. Exemplary valve structures may include electrically controlled valves and gate valves, which are available from VAT or Li-quality.

The system 100 further includes a plurality of partitions 160 disposed between each port so as to define a series of reaction zones. A reaction zone refers to any volume in fluid communication with the substrate surface to be processed. More specifically, each volume formed between the partitions, above the substrate surface, and between a gas port and a vacuum port may be referred to as a reaction zone. A lower portion of each partition extends close to substrate 110, for example, approximately 0.1 mm to 3 mm away from the substrate surface. In this manner, the partitions 160 are proximately positioned to the substrate surface at a distance sufficient to prevent cross-contamination between the precursors and sufficient to prevent the lower portions of the partitions 160 from contacting the substrate surface.

The system 100 further includes a pumping system 150 connected to the processing chamber 20. The pumping system 150 is configured to evacuate the gases out of the processing chamber 20 through one or more vacuum ports 155 disposed at the opposite end of the gas ports.

The system 100 may further include a structure to shift between a deposition mode and a cleaning mode. Generally, the cleaning mode assists the removal of unwanted by-product formation from the interior of the processing chamber 20. For example, a cleaning source (not shown) may be disposed above the processing chamber 20. The cleaning source is generally a compact system for providing cleaning reagents, typically in the form of fluorine or fluorine radicals, to remove contaminants and deposition by-products from the processing chamber 20. In one embodiment, the cleaning source is a remote plasma source that typically includes subsystems (not shown) such as a microwave generator in electrical communication with a plasma applicator, an auto-tuner and an isolator. In another embodiment, the cleaning source provides a separate flow of gas that both cleans the processing chamber 20 and removes any non-adsorbed reactive species from the processing chamber 20.

The system 100 may further include a microprocessor controller 170, which may be one of any form of a general-purpose computer processor (CPU) that can be used in an industrial setting for controlling various chambers, valves, shuttle movement, and gas injectors. The computer may use any suitable memory, such as random access memory, read only memory, floppy disk drive, hard disk, or any other form of digital storage, local or remote. Various support circuits may be coupled to the CPU for supporting the processor in a conventional manner.

Software routines may be stored in the memory or executed by a second CPU that is remotely located. The software routines are generally executed to perform process recipes or sequences. The software routines, when executed, transform the general-purpose computer into a specific process computer that controls the chamber operation so that a chamber process is performed. For example, software routines may be used to control the operation of the gas injectors. Alternatively, software routines may be performed in a piece of hardware, such as an application-specific integrated circuit.

In operation, the robot 50 delivers substrate 110 to the load lock chamber 10 through the valve 30 and places substrate 110 on the shuttle 60. As soon as the robot 50 retracts from the load lock chamber 10, the valve 30 closes. The load lock chamber 10 is evacuated to a vacuum level (e.g., in the range of 1 mTorr to about 5 mTorr) at which the processing chamber 20 is maintained. Next, the isolation valve 15 to the processing chamber 20 is opened, and the shuttle 60 is moved along the track 70. Once the shuttle 60 enters into the processing chamber 20, the isolation valve 15 closes, thereby sealing the processing chamber 20. The shuttle 60 is then moved through a series of reaction zones for processing. In one embodiment, the shuttle 60 is moved in a linear path through the chamber 20.

As the shuttle 60 moves through the processing chamber 20, the surface of substrate 110 is repeatedly exposed to the precursor of compound A coming from gas ports 125 and the precursor of compound B coming from gas ports 135, with the purge gas coming from gas ports 145 in between. The substrate surface 110 is exposed to the purge gas so that the excessive reactive material from the previous precursor that is not adsorbed by the substrate surface may be removed prior to exposing the substrate surface 110 to the next precursor. In addition, the precursors and the purge gas may flow from their respective gas ports in a direction perpendicular to the direction of the shuttle movement. The gas flow direction is indicated by arrows 198, while the shuttle movement directions are indicated by arrows 199. Consequently, the manner in which the precursors and the purge gas are delivered creates a laminar flow of the precursors and the purge gases across the substrate surface. In accordance with an embodiment of the invention, sufficient space is provided at the end of the processing chamber 20 so as to ensure complete exposure by the last gas port in the processing chamber 20 (i.e., gas port 125).

Once the shuttle 60 reaches the end of the processing chamber 20 (i.e., the substrate surface 110 has completely been exposed to every gas port in the chamber 20), the shuttle 60 returns back in a direction toward the load lock chamber 10. As the shuttle 60 moves back toward the load lock chamber 10, the substrate surface may be exposed again to the precursor of compound A, the purge gas, and the precursor of compound B, in reverse order from the first exposure. In this manner, each gas is uniformly distributed across the substrate surface 110.

When the shuttle 60 reaches the isolation valve 15, the isolation valve 15 opens to allow the shuttle 60 to move through the isolation valve 15 to the load lock chamber 10. The isolation valve 15 then closes to seal the processing chamber 20. Substrate 110 may be cooled by the load lock chamber 10 prior to being retrieved by the robot 50 for further processing. In one embodiment, substrate 110 may be transferred to another load lock chamber (not shown) when the shuttle 60 reaches the end of the processing chamber 20.

The extent to which the substrate surface 110 is exposed to each gas may be determined by the flow rates of each gas coming out of the gas port. In one embodiment, the flow rates of each gas are configured so as not to remove adsorbed precursors from the substrate surface 110. The extent to which the substrate surface 110 is exposed to the various gases may also be determined by the distance between the partitions. The larger the distance, the higher the exposure to that particular gas.

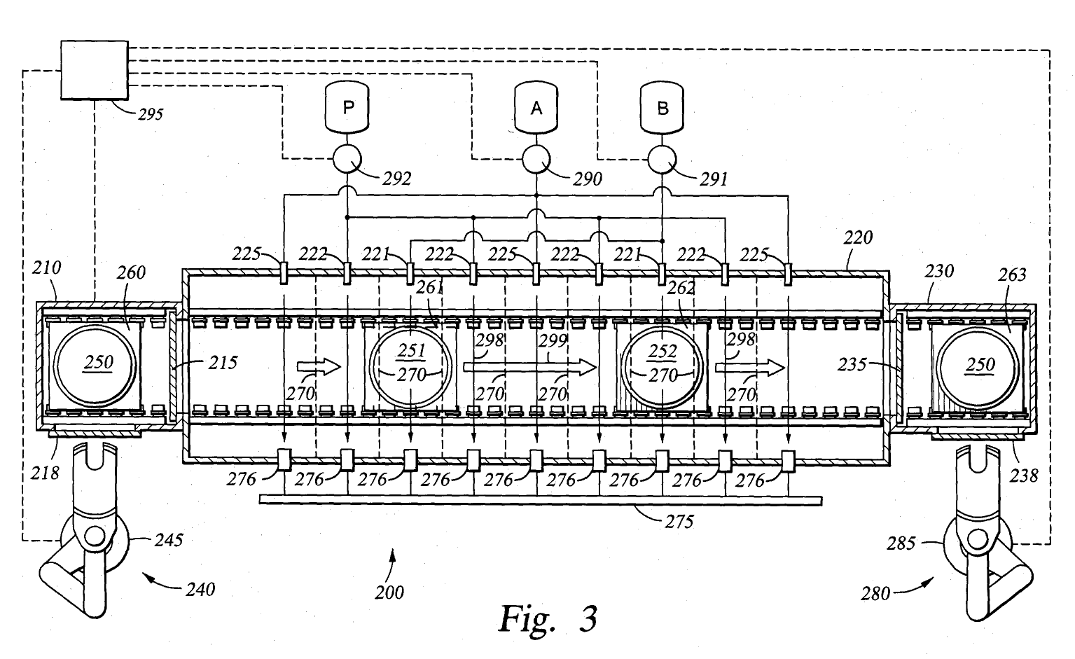

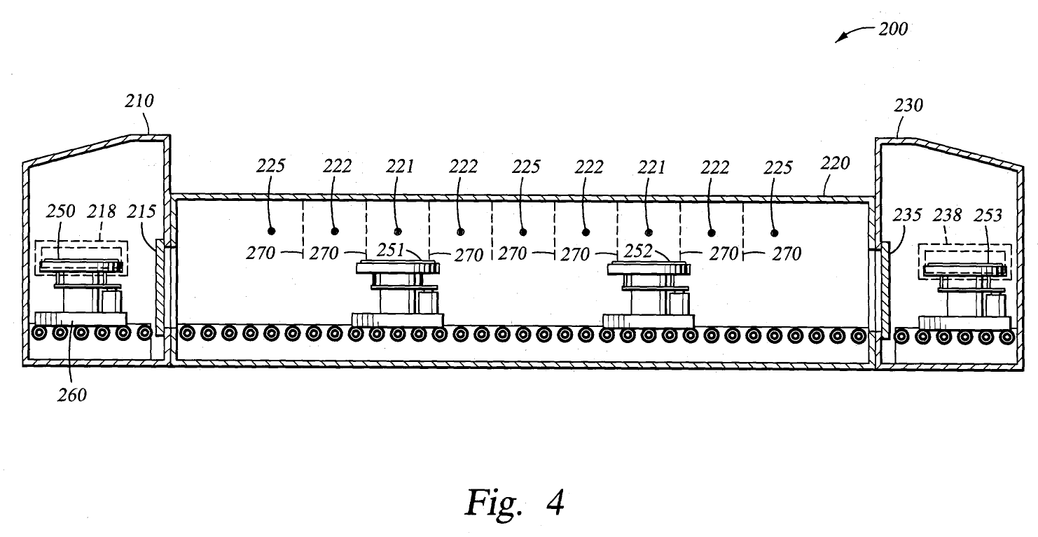

FIGS. 3 and 4 illustrate a cyclical layer deposition system or reactor 200 in which a plurality of substrates may be processed in accordance with an embodiment of the invention is illustrated. The system 200 includes a first load lock chamber 210, a processing chamber 220, and a second load lock chamber 230. Like the processing chamber 20 of the system 100, the processing chamber 220 is generally a sealable enclosure, which is operated under vacuum, or at least low pressure. The processing chamber 220 is isolated from load lock chamber 210 by an isolation valve 215. The isolation valve 215 seals the processing chamber 220 from load lock chamber 210 in a closed position, and allows substrates, e.g., substrate 250, to be transferred from load lock chamber 210 through the valve 215 to the processing chamber 220 in an open position.

Load lock chamber 210 includes a valve 218 that opens to a receiving station 240 that is serviced by a robot 245. The robot 245 is configured to deliver substrates, e.g., substrate 250, to load lock chamber 210 through the valve 218. In addition to the robot 245 and the receiving station 240, any conventional substrate transfer assembly may be used, such as a robotic substrate assembly. One example of a conventional robotic substrate transfer assembly is described in the commonly assigned U.S. Pat. No. 4,951,601, entitled “Multi-chamber Integrated Process System”, which is incorporated by reference herein.

Load lock chamber 230 is located at the opposite end of the system 100 from load lock chamber 210. Like load lock chamber 210, load lock chamber 230 is isolated from the processing chamber 220 by an isolation valve 235. The isolation valve 235 seals the processing chamber 220 from load lock chamber 230 in a closed position and allows substrates, e.g., substrate 253, to be transferred from the processing chamber 220 to load lock chamber 230 through the isolation valve 235 in an open position. Load lock chamber 230 also includes a valve 238 that opens to a receiving station 280, which is serviced by a robot 285. The robot 285 is configured to retrieve substrates, e.g., substrate 253, from load lock chamber 230.

The system 200 further includes a plurality of shuttles, e.g., shuttle 260, 261, 262 and 263, for carrying substrates, e.g., substrate 250, substrate 251, substrate 252 and substrate 253. Each shuttle is configured to move from load lock chamber 210 through the processing chamber 220 to load lock chamber 230. Once a shuttle reaches load lock chamber 230, the shuttle is returned to load lock chamber 210. In one embodiment, the shuttle may be returned to load lock chamber 210 using an elevator (not shown) coupled to load lock chamber 230 and a carrier return line (not shown) disposed above the processing chamber 220. The shuttle movement direction is indicated by arrow 299. Although only four shuttles are shown in FIGS. 3 and 4, the invention contemplates any number of shuttles configured to carry substrates through the system 200. The invention further contemplates any other mechanism, such as conveyor belts, that would facilitate processing a plurality of substrates through the system 200.

The system 200 further includes a precursor injector 290, a precursor injector 291 and a purge gas injector 292. The precursor injector 290 is configured to inject a continuous (or pulse) stream of a reactive precursor of compound A into the processing chamber 220 through a plurality of gas ports 225. The precursor injector 291 is configured to inject a continuous (or pulse) stream of a reactive precursor of compound B into the processing chamber 220 through a plurality of gas ports 221. The purge gas injector 292 is configured to inject a continuous (or pulse) stream of a non-reactive or purge gas into the processing chamber 220 through a plurality of gas ports 222. Gas ports 222 are disposed between gas ports 221 and gas ports 225 so as to separate the precursor of compound A from the precursor of compound B, thereby avoiding cross-contamination between the precursors.

The system 200 further includes a plurality of partitions 270 disposed between each port so as to define a series of reaction zones. As mentioned above, a reaction zone refers to any volume in fluid communication with the substrate surface to be processed. More specifically, each volume formed between the partitions, above the substrate surface, and between a gas port and a vacuum port may be referred to as a reaction zone. A lower portion of each partition 270 extends to a position in close proximity to the substrate surface, for example, approximately 0.1 mm to 3 mm away from the substrate surface. In this manner, the partitions 270 are proximately positioned to the substrate surface at a distance sufficient to prevent cross-contamination between the precursors, and at the same time, sufficient to prevent the lower portions of the partitions from contacting the substrate surface.

The system 200 further includes a pumping system 275 connected to the processing chamber 220. The pumping system 275 is configured to evacuate the gases out of the processing chamber 220 through one or more vacuum ports 276 disposed at the opposite end of the gas ports.

The system 200 may further include a microprocessor controller 295, which may be one of any form of a general purpose computer processor (CPU) that can be used in an industrial setting for controlling various chambers, valves, shuttle movement, and gas injectors. The computer may use any suitable memory, such as random access memory, read only memory, floppy disk drive, hard disk, or any other form of digital storage, local or remote. Various support circuits may be coupled to the CPU for supporting the processor in a conventional manner.

The system 200 is capable of processing more than one substrate at a time. In one embodiment, as soon as the robot 245 delivers a substrate to a shuttle in load lock chamber 210, the robot 245 retracts from load lock chamber 210 and picks up another substrate to be delivered to load lock chamber 210. This process is repeated until all the substrates to be processed have been delivered. As each substrate is delivered to load lock chamber 210, the substrate is transferred to the processing chamber 220 and is exposed to the various precursors and purge gases, much like the exposure previously discussed with reference to FIGS. 1 and 2.

Illustratively, FIG. 3 displays a snap shot in time in which substrate 250 is in load lock chamber 210, while substrates 251 and 252 are in the processing chamber 220, and substrate 253 is in load lock chamber 230. At this instance of time, substrate 250 is in load lock chamber 210, waiting for processing. At the same time, the surface of substrate 252 is being exposed to the precursor of compound B near its middle portion and to the purge gas at its rear portion, while the surface of substrate 251 is being exposed to the purge gas at its front portion and to the precursor of compound B near its middle portion. Also at the same instance, substrate 253 has been processed through the processing chamber 220 and is about to be retrieved by the robot 285 for further processing.

In one embodiment, load lock chamber 210 and load lock chamber 230 may be configured to perform reversed functions. That is, substrates may be delivered to load lock chamber 230 and retrieved from load lock chamber 210.

In another embodiment, in lieu of having a plurality of shuttles that continuously move in one direction, the system 200 may include a loading shuttle (not shown), a processing shuttle (not shown) and an unloading shuttle (not shown). Each shuttle is bi-directional. The loading shuttle may be configured to transfer a substrate between load lock chamber 210 and the processing chamber 220. The transfer shuttle may be configured to move a substrate through the processing chamber 220. The unloading shuttle may be configured to transfer a substrate between the processing chamber 220 and load lock chamber 230. In such an embodiment, three tracks may be disposed in the system 200, in which each track provides a path for moving each shuttle. Details of these shuttles are described in the commonly assigned U.S. Pat. No. 6,298,685, entitled “Consecutive Deposition System”, which is incorporated by reference herein.

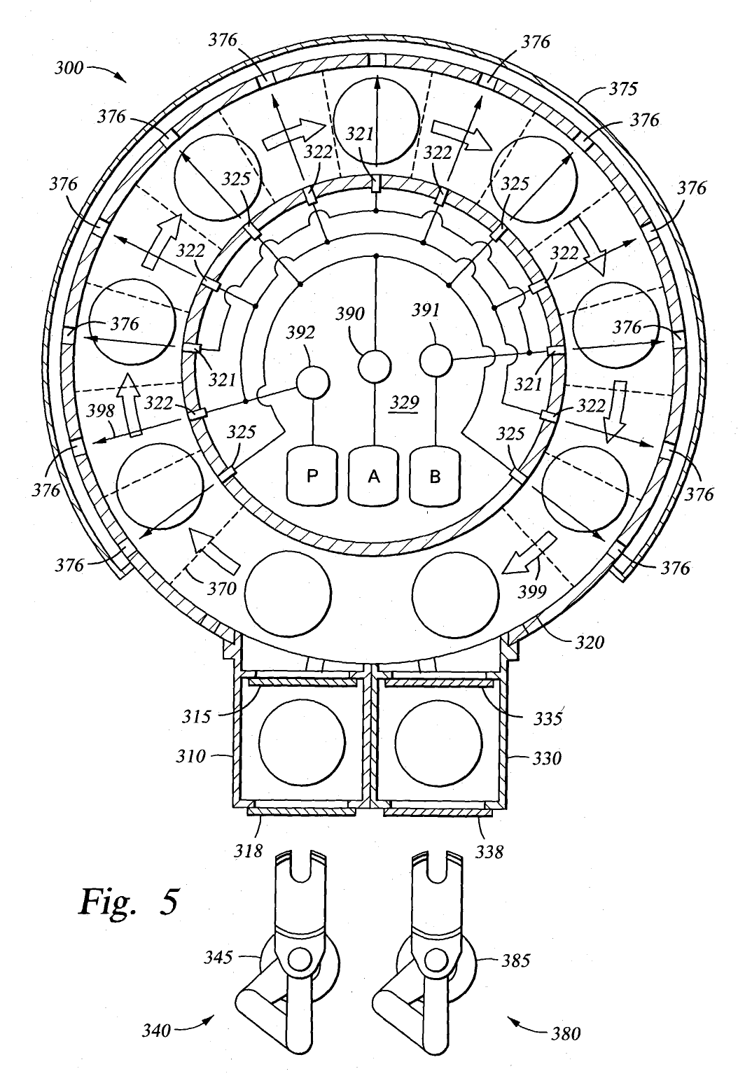

Referring now to FIG. 5, a schematic top view of a cyclical layer deposition system or reactor 300 in accordance with an embodiment of the invention is illustrated. The system 300 includes a first load lock chamber 310, a processing chamber 320, and a second load lock chamber 330. The processing chamber 320 has an annular shape, with a hollow center portion 329, in which a plurality of gas injectors is disposed. The processing chamber 320 is isolated from load lock chamber 310 by an isolation valve 315. The isolation valve 315 is configured to seal the processing chamber 320 from load lock chamber 310 in a closed position and allows substrates to be transferred from load lock chamber 310 through the valve 315 to the processing chamber 320 in an open position. Load lock chamber 310 includes a valve 318 that opens to a receiving station 340 that is serviced by a robot 345, which is configured to deliver substrates to load lock chamber 310 through the valve 318.

The system 300 further includes a second load lock chamber 330 located proximate load lock chamber 310. Like load lock chamber 310, load lock chamber 330 is isolated from the processing chamber 320 by an isolation valve 335. The isolation valve 335 seals the processing chamber 320 from load lock chamber 330 in a closed position and allows substrates to be transferred from the processing chamber 320 to load lock chamber 330 through the isolation valve 335 in an open position. Load lock chamber 330 also includes a valve 338 that opens to a receiving station 380, which is serviced by a robot 385. The robot 385 is configured to retrieve substrates from load lock chamber 330.

The system 300 further includes a precursor injector 390, a precursor injector 391 and a purge gas injector 392 disposed in the hollow center portion 329 of the processing chamber 320. The precursor injector 390 is configured to inject a continuous (or pulse) stream of a reactive precursor of compound A into the processing chamber 320 through a plurality of gas ports 325. The precursor injector 391 is configured to inject a continuous (or pulse) stream of a reactive precursor of compound B into the processing chamber 320 through a plurality of gas ports 321. The purge gas injector 392 is configured to inject a continuous (or pulse) stream of a non-reactive or purge gas into the processing chamber 320 through a plurality of gas ports 322. Gas ports 322 are disposed between gas ports 321 and gas ports 325 so as to separate precursor of compound A from precursor of compound B, thereby avoiding cross-contamination between the precursors.

The system 300 further includes a plurality of partitions 370 disposed between each port so as to define a series of reaction zones. More specifically, the partitions 370 are radially disposed between an inner perimeter of the processing chamber 320 and an outer perimeter of the processing chamber 320. A lower portion of each partition 370 extends to a position in close proximity to the substrate surface, for example, approximately 0.1 mm to 3 mm away from the substrate surface. In this manner, the partitions 370 are proximately positioned to the substrate surface at a distance sufficient to prevent cross-contamination between the precursors and sufficient to prevent the lower portions of the partitions from contacting the substrate surface.

The system 300 further includes a pumping system 375 disposed around the processing chamber 320. The pumping system 375 is configured to evacuate the gases out of the processing chamber 320 through one or more vacuum ports 376 disposed between the pumping system 375 and the processing chamber 320.

The system 300 may further include a plurality of shuttles (not shown) for carrying substrates. Each shuttle is configured to receive a substrate from the robot 345 at load lock chamber 310, carry the substrate from load lock chamber 310 through the processing chamber 320 to load lock chamber 330. The shuttle movement direction is indicated by arrow 399. The system 300 may further include a track (not shown) and a motor or gear assembly (not shown) for moving the shuttles.

In operation, the robot 345 delivers the plurality of substrates one at a time to load lock chamber 310. Once a substrate is positioned in load lock chamber 310, the substrate is transferred (e.g., by a shuttle) to the processing chamber 320. The substrate is then moved through a series of reaction zones for processing. As each substrate moves through the processing chamber 320, each substrate surface is exposed to precursor of compound A and precursor of compound B, with a purge gas in between. The purge gas is configured to remove the excessive reactive material from the previous precursor that is not adsorbed by the substrate surface prior to exposing the substrate surface to the next precursor.

The substrates move in a circular fashion as indicated by arrow 399, while the gases flow in a radial direction, as indicated by arrows 398. Consequently, the precursors and the purge gases flow across the surface of each substrate in a direction perpendicular to the substrate movement direction. As a result, the precursors and the purge gas flow from their respective gas ports in a direction toward the vacuum ports so as to provide a laminar flow of the precursors and the purge gases across the substrate surface. In this manner, the system 300 is able to uniformly distribute the precursors and the purge gas across each substrate surface.

In one embodiment, the substrate movement direction may be reversed. In such an embodiment, the substrates are loaded at load lock chamber 330 and unloaded at load lock chamber 310.

Variations in the orientation of the shuttle, substrates, robot, chambers, and other system components are contemplated by the invention. Additionally, all movements and positions, such as “above”, “top”, “below”, “under”, “bottom”, “side”, described herein are relative to positions of objects such as the chambers and shuttles. Accordingly, it is contemplated by the present invention to orient any or all of the components to achieve the desired movement of substrates through a processing system.

While the foregoing is directed to embodiments of the present invention, other and further embodiments of the invention may be devised without departing from the basic scope thereof, and the scope thereof is determined by the claims that follow.

1. An cyclical layer deposition system, comprising:
a processing chamber;
at least one load lock chamber connected to the processing chamber;
a plurality of gas injectors connected to the processing chamber, the gas injectors being configured to deliver one or more gas streams into the processing chamber; and
at least one shuttle movable between the at least one load lock chamber and the processing chamber.

2. The system of claim 1, further comprising a plurality of reaction zones defined within the processing chamber.

3. The system of claim 2, further comprising a plurality of partitions separating the reaction zones, the partitions being disposed within the processing chamber.

4. The system of claim 2, wherein each reaction zone comprises a gas port and a vacuum port.

5. The system of claim 4, wherein the gas port is configured to transmit one of a precursor and a purge gas.

6. The system of claim 3, wherein the partitions are positioned so as to limit cross-contamination between the gas streams.

7. The system of claim 1, further comprising a plurality of gas ports disposed on the processing chamber, the gas ports being configured to transmit the gas streams from the gas injectors to the processing chamber.

8. The system of claim 1, further comprising a pumping system connected to the processing chamber, the pumping system being configured to evacuate the gas streams out of the processing chamber.

9. The system of claim 8, further comprising a plurality of vacuum ports disposed on the processing chamber, the vacuum ports being configured to transmit the gas streams out of the processing chamber.

10. The system of claim 1, wherein the at least one shuttle is configured to carry a substrate between the at least one load lock chamber and the processing chamber.

11. The system of claim 1, wherein the at least one shuttle is configured to move bidirectionally between the at least one load lock chamber and the processing chamber.

12. The system of claim 1, wherein the gas streams flow in a direction perpendicular to a movement direction of the at least one shuttle so as to provide a laminar flow of the gas streams across a substrate surface.

13. The system of claim 1, wherein the gas streams comprise at least one of a first compound, a second compound and a purge gas.

14. The system of claim 13, wherein the first compound comprises one or more compounds selected from a group consisting of titanium tetrachloride (TiCl₄), tungsten hexafluoride (WF₆), tantalum pentachloride (TaCl₅), titanium iodide (TiI₄), titanium bromide (TiBr₄), tetrakis (dimethylamido) titanium (TDMAT), pentakis (dimethyl amido) tantalum (PDMAT), tetrakis (diethylamido) titanium (TDEAT), tungsten hexacarbonyl (W(CO)₆), tungsten hexachloride (WCl₆), tetrakis(diethylamido) titanium (TDEAT), pentakis (ethyl methyl amido) tantalum (PEMAT), and pentakis(diethylamido)tantalum (PDEAT).

15. The system of claim 13, wherein the second compound comprises one or more compounds selected from a group consisting of ammonia (NH₃), hydrazine (N₂H₄), monomethyl hydrazine (CH₃N₂H₃), dimethyl hydrazine (C₂H₆N₂H₂), t-butylhydrazine (C₄H₉N₂H₃), phenylhydrazine (C₆H₅N₂H₃), 2,2′-azoisobutane ((CH₃)₆C₂N₂), ethylazide (C₂H₅N₃), and nitrogen (N₂).

16. The system of claim 13, wherein the purge gas comprises at least one of hydrogen, nitrogen, argon, and helium.

17. The system of claim 1, wherein the processing chamber has an annular configuration.

18. The system of claim 1, wherein the processing chamber has an annular configuration and defines an inner perimeter portion and an outer perimeter portion.

19. The system of claim 18, further comprising a plurality of gas ports disposed on the inner perimeter portion of the processing chamber, the gas ports being configured to transmit the gas streams from the gas injectors to the processing chamber.

20. The system of claim 18, further comprising a plurality of vacuum ports disposed on the outer perimeter portion of the processing chamber, the vacuum ports being configured to transmit the gas streams out of the processing chamber.

21. The system of claim 18, wherein the gas streams flow radially from the inner perimeter portion of the processing chamber.

22. The system of claim 18, wherein the at least one shuttle is configured to carry a substrate around the inner perimeter portion of the processing chamber.

23. The system of claim 18, further comprising a plurality of partitions disposed between the inner perimeter portion of the processing chamber and the outer perimeter portion of the processing chamber.

24. A method of processing a substrate, comprising:
disposing a substrate in a first load lock chamber;
transferring the substrate from the first load lock chamber to a processing chamber;
moving the substrate through the processing chamber; and
delivering one or more gas streams into the processing chamber and across a surface of the substrate while moving the substrate through the processing chamber.

25. The method of claim 24, further comprising, subsequent to delivering the gas streams, transferring the substrate from the processing chamber to a second load lock chamber.

26. The method of claim 24, further comprising, subsequent to delivering the gas streams, transferring the substrate from the processing chamber to the first load lock chamber.

27. The method of claim 24, wherein the gas streams flow in a direction perpendicular to a movement of the substrate.

28. The method of claim 24, wherein the gas streams flow in a direction perpendicular to a movement of the substrate so as to provide a laminar flow of the gas streams across the substrate surface.

29. The method of claim 24, wherein the gas streams comprise at least one of a first compound, a second compound and a purge gas.

30. The method of claim 24, wherein delivering the gas streams comprises:
depositing at least one of a first compound and a second compound; and
depositing a purge gas.

31. The method of claim 29, wherein the first compound comprises one or more compounds selected from a group consisting of titanium tetrachloride (TiCl₄), tungsten hexafluoride (WF₆), tantalum pentachloride (TaCl₅), titanium iodide (TiI₄), titanium bromide (TiBr₄), tetrakis (dimethylamido) titanium (TDMAT), pentakis (dimethyl amido) tantalum (PDMAT), tetrakis (diethylamido) titanium (TDEAT), tungsten hexacarbonyl (W(CO)₆), tungsten hexachloride (WCl₆), tetrakis(diethylamido) titanium (TDEAT), pentakis (ethyl methyl amido) tantalum (PEMAT), and pentakis(diethylamido)tantalum (PDEAT).

32. The method of claim 29, wherein the second compound comprises one or more compounds selected from a group consisting of ammonia (NH₃), hydrazine (N₂H₄), monomethyl hydrazine (CH₃N₂H₃), dimethyl hydrazine (C₂H₆N₂H₂), t-butylhydrazine (C₄H₉N₂H₃), phenylhydrazine (C₆H₅N₂H₃), 2,2′-azoisobutane ((CH₃)₆C₂N₂), ethylazide (C₂H₅N₃), and nitrogen (N₂).

33. The method of claim 29, wherein the purge gas comprises at least one of hydrogen, nitrogen, argon, and helium.

34. A method of processing a substrate, comprising:
disposing a substrate in a first load lock chamber;
transferring the substrate from the first load lock chamber to a processing chamber;
moving the substrate through the processing chamber; and
delivering one or more gas streams into a plurality of reaction zones defined within the processing chamber.

35. The method of claim 34, wherein each reaction zone is in fluid communication with a surface of the substrate.

36. The method of claim 34, wherein delivering the gas streams into the plurality of reaction zones comprises delivering at least one of a precursor and a purge gas into each reaction zone.

37. A method of processing a plurality of substrates, comprising:
moving a plurality of substrates through a processing chamber; and
delivering one or more gas streams into the processing chamber and across a surface of each substrate while moving the substrates through the processing chamber.

38. The method of claim 37, wherein the gas streams flow in a direction perpendicular to a movement of the substrates.

39. The method of claim 37, wherein the gas streams flow in a direction perpendicular to a movement of the substrates so as to provide a laminar flow of the gas streams across the surface of each substrate.

40. The method of claim 37, wherein the gas streams comprise at least one of a first compound, a second compound and a purge gas.

41. The method of claim 37, wherein delivering the gas streams into the processing chamber comprises delivering the gas streams into a plurality of reaction zones defined within the processing chamber.

42. The method of claim 40, wherein delivering the gas streams into the processing chamber comprises delivering at least one of a precursor and a purge gas into each reaction zone.

43. A method of processing a plurality of substrates, comprising:
moving the substrates through the processing chamber in a circular fashion; and
delivering one or more gas streams into the processing chamber and across a surface of each substrate while moving the substrates through the processing chamber.

44. The method of claim 43, wherein the gas streams flow radially from a center portion of the processing chamber.

45. The method of claim 43, wherein the gas streams flow in a direction perpendicular to a movement of the substrates.

46. The method of claim 43, wherein the gas streams flow in a direction perpendicular to a movement of the substrates so as to provide a laminar flow of the gas streams across the surface of each substrate.

47. The method of claim 43, wherein the gas streams comprise at least one of a first compound, a second compound and a purge gas.
